(19) United States
(12) Patent Application Publication
(10) Pub. No.: US 2010/0195415 A1
(43) Pub. Date: Aug. 5, 2010

(54) Semiconductor memory device and reading method therefor

(75) Inventor: Akiyoshi Seko, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/656,484

(22) Filed: Feb. 1, 2010

(30) Foreign Application Priority Data
Feb. 4, 2009 (JP) 2009-023248

(51) Int. Cl. G11C 5/14; G11C 7/02; G11C 7/00

(52) U.S. Cl. 365/189.09; 365/207; 365/203

(57) ABSTRACT

A memory device is configured such that, in a read access: a first switch and a second switch are turned on in a pre-charge period before a memory cell is accessed so that charges of a bit line charge voltage generating circuit are distributed to a bit line and a reference bit line, to thereby charge the bit line and the reference bit line to an initial voltage. After the charge, a selected memory cell is connected to the bit line, the reference bit line is connected to a reference voltage generating circuit, and a voltage differential type sense amplifier amplifies a difference voltage between a voltage of the bit line decreased by discharge of the selected memory cell and a voltage of the reference bit line generated by the reference voltage generating circuit, to thereby read out memory cell data.

This application is based upon and claims the benefit of priority from Japanese patent application No. 2009-023248, filed on Feb. 4, 2009, the disclosure of which is incorporated herein in its entirety by reference.

### BACKGROUND OF THE INVENTION

1. Field of the Invention

The present invention relates to a semiconductor memory device, and more particularly, to a semiconductor memory device capable of being read at high speed and a reading method therefor.

2. Description of the Related Art

There are two types of semiconductor memory devices, that is, a volatile memory which does not retain stored information if power supply is turned off, and a non-volatile memory which retains the stored information even if power supply is turned off. For instance, a dynamic random access memory (DRAM) and a static random access memory (SRAM) are volatile memories while an electrically erasable programmable read only memory (EEPROM) and a flash memory are non-volatile memories. The volatile memory cannot retain the stored information when power supply is turned off, but has an advantage that it can be accessed at high speed and at random. In contrast, the non-volatile memory has an advantage that it can maintain the stored information even if power supply is turned off, but has a disadvantage that it can be accessed only at medium speed and cannot be accessed at random.

As described above, each of the current volatile memory and the current non-volatile memory have an advantage and a disadvantage. Therefore, there is developed a next generation semiconductor memory device, which has both the advantages, i.e., a high speed, random access, and non-volatile semiconductor memory device. Examples of the next generation semiconductor memory device include a phase change memory (PCRAM), a magnetic resistance memory (MRAM), and a resistance change memory (ReRAM). For instance, the phase change memory utilizes characteristics of a phase change element made of a chalcogenide material (Ge, Sb, Te), which becomes an amorphous state (high resistance) or a crystalline state (low resistance) when heat is applied thereto. Controlling an applied voltage and application period, the memory element is changed between a high resistance (reset) state and a low resistance (set) state utilizing Joule heat generated by write current.

As a reading method for those memories, there are a voltage difference amplifying method of reading a voltage difference and a current difference amplifying method of reading a current difference. Both the voltage difference amplifying method and the current difference amplifying method are required to be capable of reading a small signal level from the memory element securely at higher speed.

M. Aoki et al, Symposium on VLSI Circuits Digest of Technical Papers P. 170 11-4 (2005) (Non-patent Document 1) discloses the voltage difference amplifying method for a non-volatile memory cell. Non-patent Document 1 is incorporated in this application by reference. FIGS. 10 and 11 of Non-patent Document 1 disclose a sensing method in which a bit line pair is pre-charged to ½ VDD (Vread/2), a memory node is charged to a voltage close to approximately Vread/2, and the memory node voltage is read out.

On the other hand, as the voltage difference amplifying method for a volatile memory cell such as a DRAM, FIGS. 3 and 4 of Japanese Patent Application Laid-open No. 2008-159188 (Patent Document 1) disclose an overdrive voltage (VOD) technology, in which a power supply voltage of a sense amplifier (source VDD of the SAP) is raised at an early stage of sensing so that differential sensibility of the sense amplifier is improved. US Patent Application Publication No. US2008/0151674 A1 (Patent Document 2), which is a counterpart of Japanese Patent Application Laid-open No. 2008-159188 (Patent Document 1), also discloses the same technology. Patent Document 1 and Patent Document 2 are incorporated in this application by reference.

In addition, Kwang-Jin Lee et al, IEEE J. solid-state circuits vol. 43 No. 1 P. 150 (2008) (Non-patent Document 2) discloses a reading technology for a non-volatile memory cell according to the current difference amplifying method. The current difference amplifying method of Non-patent Document 2 is a constant current type current difference amplifying method controlled by VBIAS and NPBIAS as illustrated in FIGS. 3 and 5 of Non-patent Document 2. In the current difference amplifying method, there is disclosed a technology in which VCMP controls a memory side bit line to be low voltage, and a differential margin is secured between a sense side bit line (SDL) and a reference voltage (VREF) by raising the SDL by two steps (0 V to VDD to VPPSA). Here, Non-patent Document 2 is incorporated in this application by reference.

### SUMMARY

It is supposed that the above-mentioned voltage difference amplifying method of Non-patent Document 1 is adopted in a bit line and a cell structure that are described later as an embodiment of the present invention. Cells of the present invention are arranged in the order of a bit line, a memory (variable resistance) element, a selecting element, and GND. Therefore, when the bit line is to be charged to a constant voltage by using a constant voltage generating source like the voltage Vread/2 in Non-patent Document 1, a parasitic capacitance contact between a variable resistance element and an element selecting device in a non-selected cell is also charged to the same potential as the bit line. However, charging of the parasitic capacitance is performed by charge transfer from the bit line via the memory element. Therefore, if the memory element is a high resistance element, there is a problem that charging of the parasitic capacitance contact is so slow that charging period of the bit line becomes long. In addition, if several tens of thousands of bit lines are read simultaneously by the same number of sense amplifiers in the array, there are problems that the supply capability of the constant voltage generating source is decreased because of large current consumption and that noise is generated on the GND potential due to a parasitic resistance of wiring or other factors.

Further, in the phase change memory, if a voltage of a predetermined value or higher is applied to the phase change element, cell information may be rewritten. For instance, if the predetermined voltage value (threshold value Vh) is 0.6 volts, the voltage to be applied to the phase change element for reading information must be lower than 0.6 volts. Therefore, in Non-patent Document 2, the bit line is charged by setting the voltage of the bit line to a value that is the same as or lower than sum voltage of the threshold value Vh and a built-in potential of a diode connected in series by a transistor whose gate input is VCMP, and the reading is performed by constant current.

On the other hand, in a volatile memory such as a DRAM, the overdrive voltage may be used for temporarily raising the voltage of the power supply of the sense amplifier (source VDD of the SAP) as described in Patent Document 1. However, as to the pre-charge of the bit line, after the reading is finished and a selected cell is electrically separated, a selected bit line and a reference bit line, which are fixed to one and the other of a HIGH potential and a LOW potential, are short-circuited to each other so as to be the intermediate potential of HIGH/2. Note that Non-patent Document 1 also employs the same method by electrically separating the cell when the bit line is charged. When the charge (pre-charge) of the bit line is performed, the bit line and the reference bit line are not supplied with charges externally in this method. Therefore, it is necessary to provide the reference bit line having the same capacitance (substantially the same structure) as the bit line for each bit line pair or for each sense amplifier. Therefore, those methods cannot be applied to the bit line structure of the non-volatile memory in the embodiment of the present invention that is described later (the case where the reference bit line is shared by a plurality of sense amplifiers).

The present invention seeks to solve one or more of the above-mentioned problems in a non-volatile memory having an array structure as in an embodiment of the present invention.

In one embodiment, there is provided a device comprising: at least one memory array including a plurality of memory cells, each of the memory cells adapted to store data based on a difference of resistance; a plurality of bit lines each arranged to be connected to the memory cells; a sense amplifier of a voltage differential type; a voltage generating circuit adapted to charge a selected bit line and a reference bit line to a first voltage higher than an initial voltage prior to access; a first switch and a second switch controlled to couple the voltage generating circuit to the selected bit line and the reference bit line, respectively; and a reference voltage generating circuit capable of being coupled to the reference bit line.

In the access, the first switch and the second switch are tuned on in a pre-charge period before the memory cell is accessed so that charges provided by the voltage generating circuit are distributed to share between the selected bit line and the reference bit line, to thereby charge the selected bit line and the reference bit line to the initial voltage, and after pre-charge, a selected memory cell is connected to the selected bit line, the reference bit line is connected to the reference voltage generating circuit, and the sense amplifier amplifies a difference voltage between a voltage of the selected bit line decreased by discharge of the selected memory cell and a voltage of the reference bit line developed by coupling to the reference voltage generating circuit.

In another embodiment, a device comprises: a bank including a block of multiple mats arranged in matrix; each mat including a memory array which includes a of a plurality of memory cells adapted to store data based on a difference of resistance, a plurality of bit lines each arranged to be connected to the memory cells, and at least one sense amplifier of a voltage differential type; voltage generating circuits disposed at corners of the block, each of voltage generating circuits adapted to charge a selected bit line and a reference bit line to a first voltage higher than an initial voltage prior to access, a first switch and a second switch controlled to couple the voltage generating circuit to the sense bit line and the reference bit line, respectively; override capacitors arranged along four sides of the block and coupled to the voltage generating circuits; power supply voltage wirings formed across the block so as to form a cross shape in each mat, the power supply voltage wirings connected to the override capacitors and the voltage generating circuit; and a reference voltage generating circuit capable of being coupled to the reference bit line;

In the access, the first switch and the second switch are tuned on in a pre-charge period before the memory cell is accessed so that charges provided by the voltage generating circuit are distributed to share between the selected bit line and the reference bit line, to thereby charge the selected bit line and the reference bit line to the initial voltage; and after pre-charge, a selected memory cell is connected to the selected bit line, the reference bit line is connected to the reference voltage generating circuit, and the sense amplifier amplifies a difference voltage between a voltage of the selected bit line decreased by discharge of the selected memory cell and a voltage of the reference bit line developed by coupling to the reference voltage generating circuit.

In one embodiment, there is provided a method comprising: reading data from a device, wherein the device comprises a plurality of memory cells adapted to store data by a difference of resistance; a plurality of bit lines each connected to the memory cells; a sense amplifier adapted to amplify a voltage difference between a selected bit line and a reference bit line developed by selecting a memory cell; and a charge voltage generating circuit: the reading data from the device comprising: charging an output capacitance of the charge voltage generating circuit to a high voltage higher than an initial voltage; supplying charges that are charged to the high voltage to the selected bit line and the reference bit line, so as to set the selected bit line and the reference bit line to the initial voltage; discharging the selected bit line in accordance with data stored in a selected memory cell; and amplifying a difference voltage between a voltage of the discharged selected bit line and the voltage of the reference bit line by the sense amplifier, to thereby read out the stored data of the memory cell.

According to the embodiment, the bit line and the reference bit line are charged to the initial voltage by using the charge that is charged to a voltage higher than the initial voltage. The charges that are charged to high voltage are distributed to the bit line and the reference bit line for performing charge sharing, and hence the bit line and the reference bit line can be charged to the initial voltage at high speed. Because the bit line and the reference bit line can be charged to the initial voltage at high speed, the device can be read at high speed. In addition, the charges that are charged to high voltage can be prepared in sufficient time in the charge voltage generating circuit except for a period for charging the bit line and for reading out information. Therefore, maximum current in the charge voltage generating circuit can be controlled, and noise due to the charge voltage generating circuit can be reduced compared with the case where the constant voltage power supply is used.

### BRIEF DESCRIPTION OF THE DRAWINGS

The above features and advantages of the present invention will be more apparent from the following description of certain preferred embodiments in conjunction with the accompanying drawings, in which:

FIG. 1A is a schematic structural diagram for illustrating a basic structure of an embodiment of the present invention;

FIG. 1B is a read timing chart in the structure of FIG. 1A;

FIG. 2 is a block diagram illustrating a general structure of a semiconductor memory device according to the embodiment of the present invention;

FIG. 3 is a circuit diagram illustrating a detailed part of the semiconductor memory device according to the embodiment of the present invention;

FIG. 4 is a read timing chart of the semiconductor memory device illustrated in FIGS. 2 and 3;

FIG. 5 is a circuit diagram of a bit line charge voltage generating circuit which is used in the embodiment of the present invention;

FIG. 6A is a layout and wiring diagram of the bit line charge voltage generating circuit in a bank of the semiconductor memory device according to the embodiment of the present invention;

FIG. 6B is a layout and wiring diagram of the bit line charge voltage generating circuit in a mat of the semiconductor memory device according to the embodiment of the present invention;

FIG. 7 is a write timing chart of the semiconductor memory device illustrated in FIGS. 2 and 3;

FIG. 8 is another circuit diagram of a reference voltage generating circuit which is used in the embodiment of the present invention; and

FIG. 9 is a read timing chart in a case where the reference voltage generating circuit of FIG. 8 is used.

### DETAILED DESCRIPTION OF EXEMPLARY EMBODIMENTS

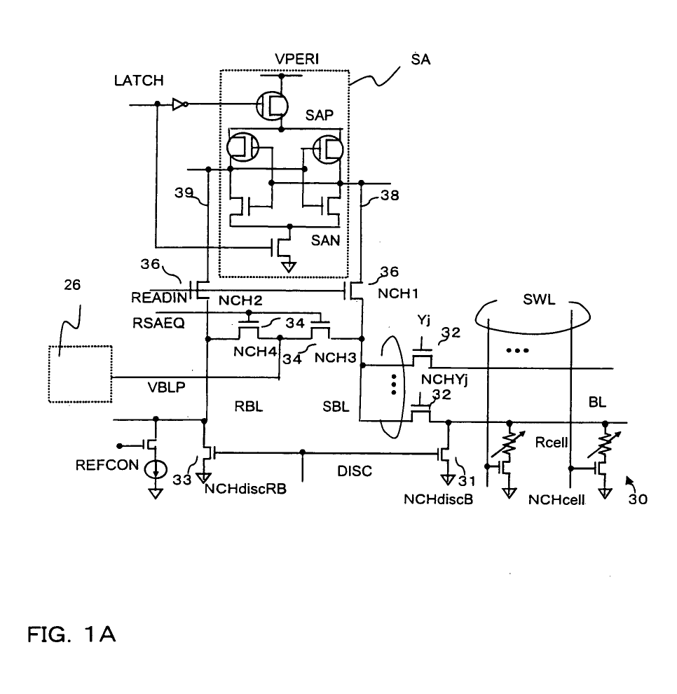

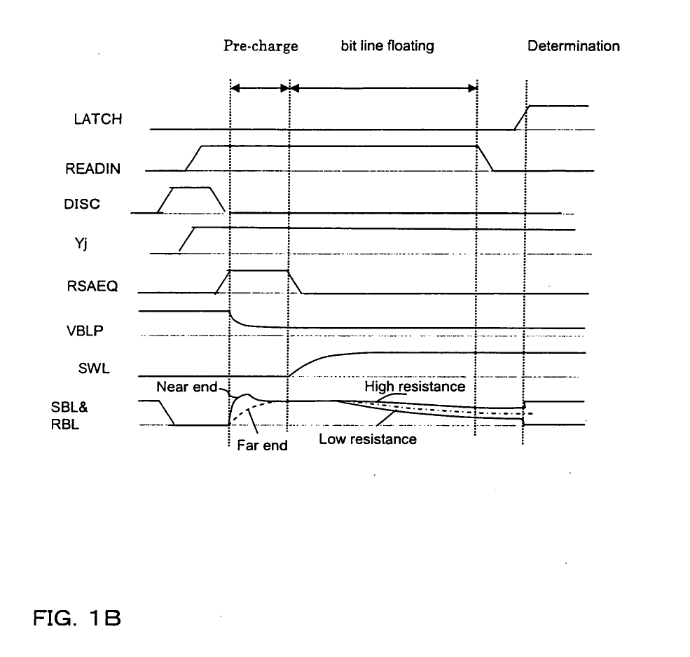

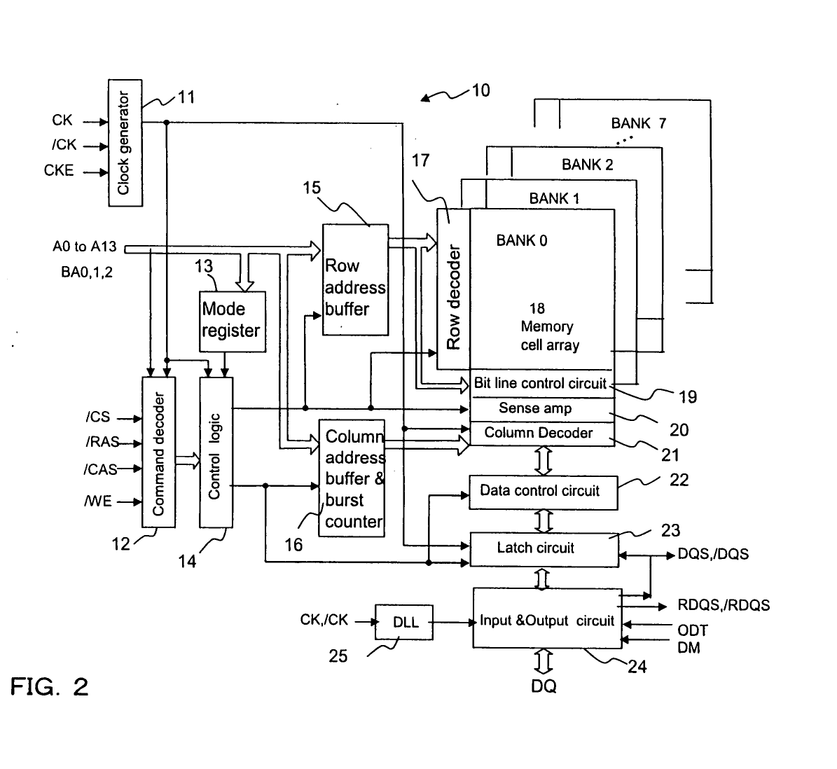

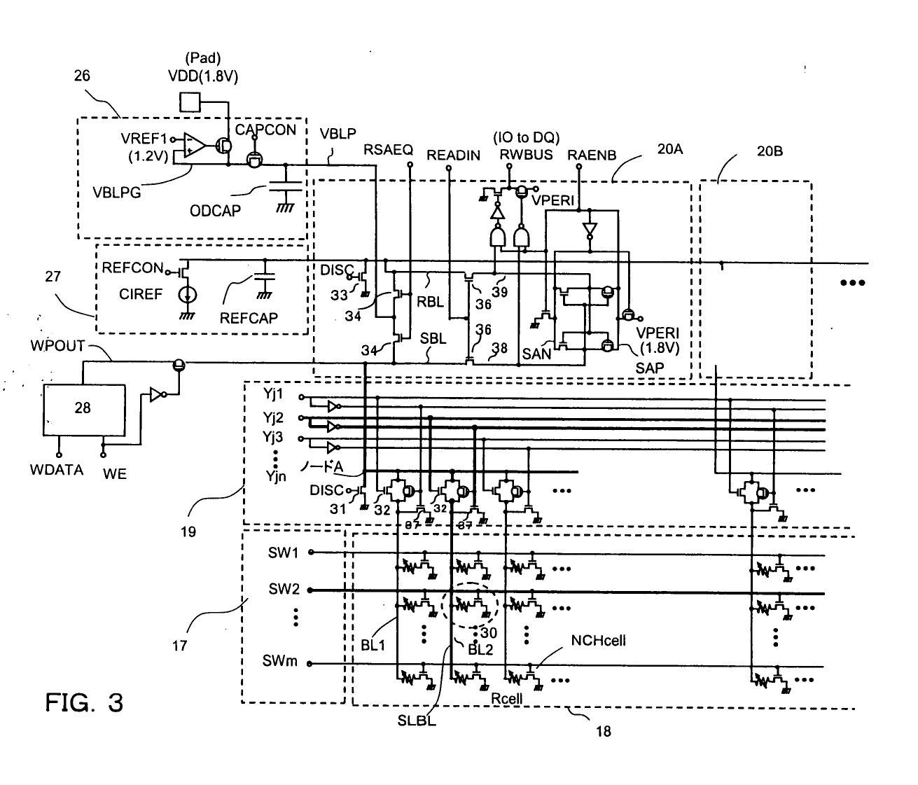

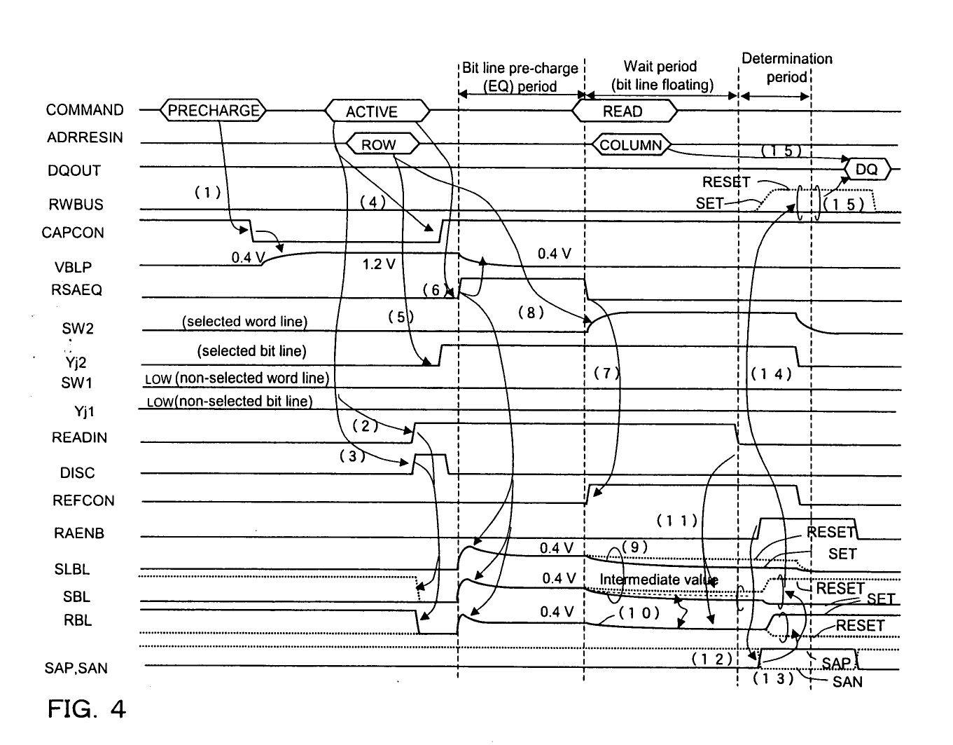

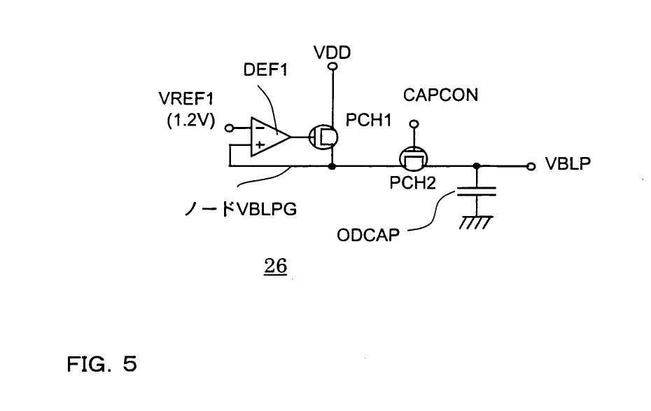

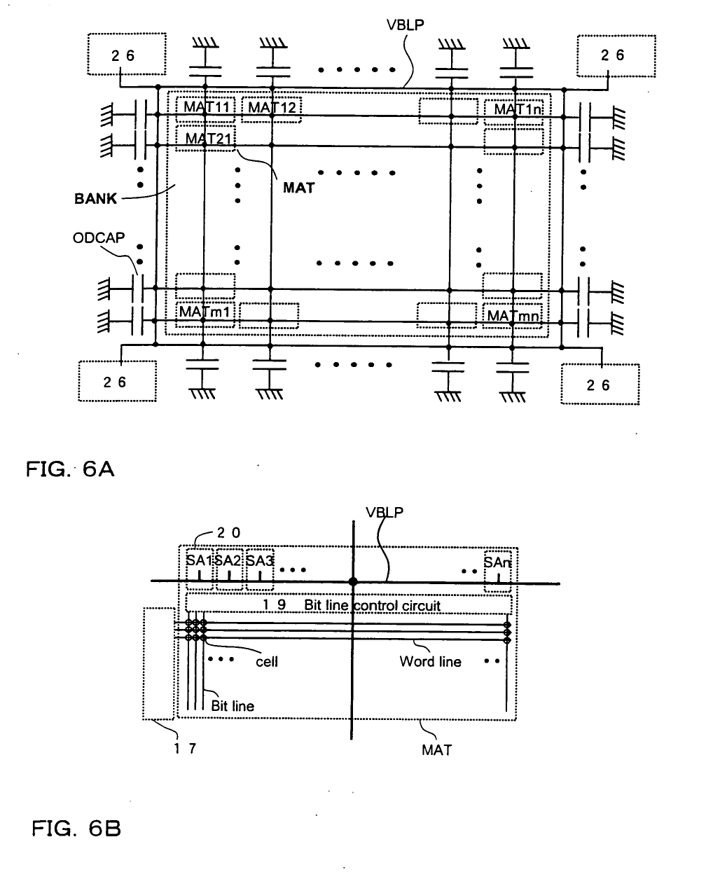

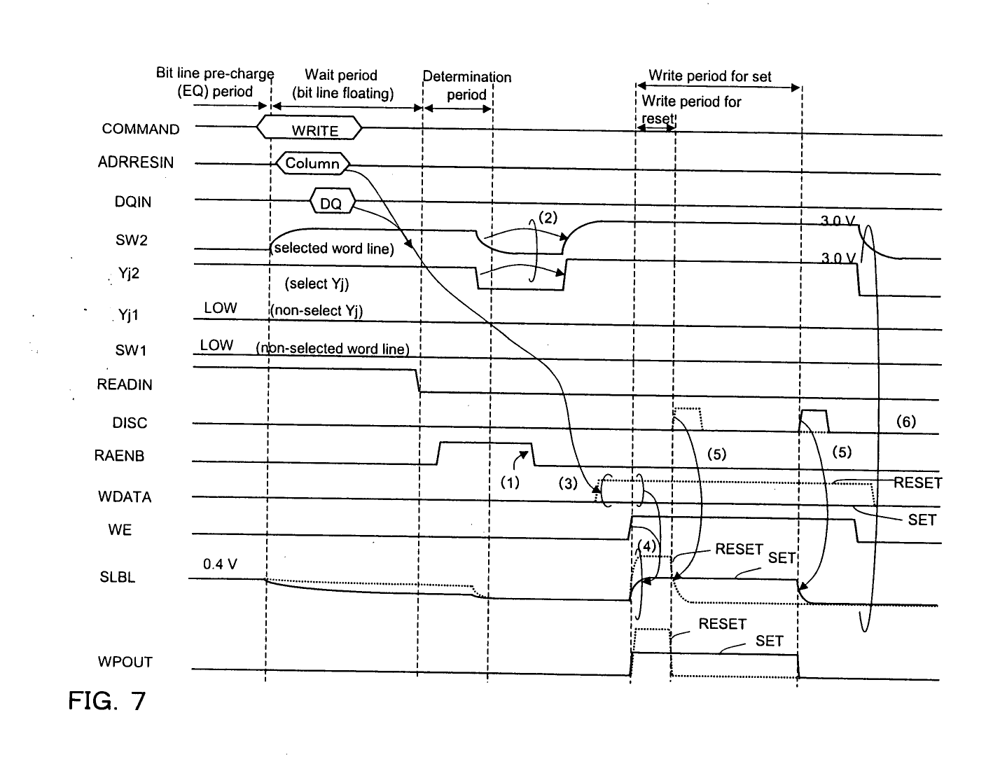

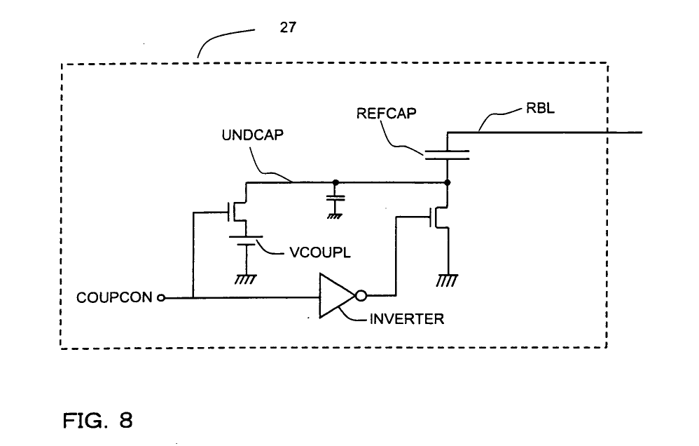

An embodiment of the present invention is described in detail with reference to the attached drawings. FIGS. 1A and 1B are a schematic structural diagram for illustrating a basic structure of a semiconductor memory device according to the embodiment of the present invention and a read timing chart thereof, respectively. FIG. 2 is a general structure diagram of the semiconductor memory device, FIG. 3 is a detailed block diagram thereof, and FIG. 4 is a read timing chart thereof. FIG. 5 is a circuit diagram of a bit line charge voltage generating circuit that is used in the embodiment, FIGS. 6A and 6B are diagrams illustrating layouts of the bit line charge voltage generating circuit and wirings of a power supply respectively in a bank and a mat of the semiconductor memory device. FIG. 7 illustrates a write timing chart of the semiconductor memory device according to the embodiment.

In FIG. 1A, the basic structure includes memory cells 30 (Rcell and NCHcell), bit line selecting switches 32 (NCHYj), a bit line pair (sense bit line SBL and reference bit line RBL), switching elements 34 (NCH3 and NCH4) for controlling charging of the bit line pair, a bit line charge voltage generating circuit 26, bit line connection switching elements 36 (NCH1 and NCH2) for controlling connection or disconnection between the bit line pair (SBL and RBL) and a first bit line 38 or a second bit line 39 of a sense amplifier SA, and the sense amplifier SA.

The sense amplifier SA is a voltage differential type sense amplifier, and comprises a flip-flop including a CMOS circuit to which voltages of the first bit line 38 and the second bit line 39 are supplied. In the flip-flop, a PMOS and an NMOS are disposed on the high power supply voltage side and the low power supply voltage side, respectively. When a latch signal LATCH is enabled, the PMOS and the NMOS are turned on, with the result that a high power supply voltage SAP and a low power supply voltage SAN are supplied to the sense amplifier SA. Thus, a voltage difference between the first bit line and the second bit line is amplified.

Between the bit line pair (SBL and RBL), and the first bit line and the second bit line of the sense amplifier, bit line connecting transistors (NCH1 and NCH2) are disposed as the bit line connection switching elements (transistors) 36. The bit line connecting transistors (NCH1 and NCH2) connect or disconnect the bit line pair (SBL and RBL) with the differential inputs (the first bit line and the second bit line) of the sense amplifier in accordance with a bit line connection signal READIN supplied to the gates thereof. The gate, the drain, and the source of the bit line connecting transistor NCH1 are connected to the bit line connection signal READIN, the sense bit line, and the first bit line of the sense amplifier, respectively. The gate, the drain, and the source of the bit line connecting transistor NCH2 are connected to the bit line connection signal READIN, the reference bit line, and the second bit line of the sense amplifier, respectively.

As the charge control switching element 34 of the bit line pair (SBL and RBL), charge transistors (NCH3 and NCH4) are connected to the respective bit lines of the bit line pair. The charge transistors (NCH3 and NCH4) are turned on by an equalize signal RSAEQ so as to charge the bit lines to the same voltage as an initial voltage. The gate, the drain, and the source of the charge transistor NCH3 are connected to the equalize signal RSAEQ, a bit line charge high voltage VBLP, and the sense bit line, respectively. The gate, the drain, and the source of the charge transistor NCH4 are connected to the equalize signal RSAEQ, the bit line charge high voltage VBLP, and the reference bit line, respectively. The bit line charge high voltage VBLP is generated by using the bit line charge voltage generating circuit 26. The bit line charge high voltage VBLP is a voltage higher than the initial voltage to which the bit lines (SBL and RBL) are charged.

The sense bit line SBL is connected to a plurality of bit lines BL1-BLn which respectively include bit line selecting switches 32 (transistors NCHYj). Among the plurality of bit lines, the bit line connected to the bit line selecting transistor (NCHYj) enabled by the bit line selecting signal Yj is selected. Each bit line is connected to a plurality of memory cells and a reset transistor 31 (NCHdiscB) for discharging the charges on the bit line so as to be reset to the ground voltage. The gate, the drain, and the source of the reset transistor 31 (NCHdiscB) are connected to a reset signal DISC, a bit line BL, and the ground voltage, respectively.

The memory cell includes the access transistor NCHcell and the memory element Rcell. The memory element Rcell is a non-volatile memory element which stores data or information by a difference in resistance. The access transistor NCHcell is a cell selecting element for accessing the memory cell. The gate, the drain, and the source of the access transistor NCHcell are connected to a word line, an end of the memory element Rcell, and the ground voltage, respectively. In addition, the other end of the memory element Rcell is connected to the bit line BL. A plurality of the memory cells are arranged in matrix in the bit line direction and in the word line direction. The bit line is connected to the plurality of memory cells, and each of the memory cells is selected by the cell selecting element in the word line direction and by the bit line selecting transistor 32 in the bit line direction.

Among these memory cells, the bit line selecting transistor (NCHYj) selects the bit line BL, and then the word line selects the access transistor (NCHcell), with the result that a specific memory cell is selected. The data stored in the memory cell that is selected as described above is read out by being supplied to the sense amplifier via the bit line BL, the sense bit line SBL, and the bit line connecting transistor (NCH1). If the memory element Rcell has a high resistance, the sense bit line SBL connected to the memory element Rcell has a higher voltage compared with the reference bit line. In addition, if the memory element Rcell has a low resistance, the sense bit line SBL connected to the memory element Rcell has a low voltage.

On the other hand, the reference bit line (RBL) is connected to a reset transistor 33 (NCHdiscRB) for discharging the reference bit line so as to be reset to the ground voltage. The reference bit line is also connected to a constant current source for supplying constant reference current, and a selecting transistor. The constant current source may be realized by using a transistor or by using a resistor (the constant current source is not required to supply strictly constant current). The gate, the drain, and the source of the reset transistor NCHdiscRB are connected to the reset signal DISC, the reference bit line RBL, and the ground voltage, respectively. In addition, the gate, the drain, and the source of the selecting transistor are connected to a reference constant current source control signal REFCON, the reference bit line RBL, and an end of the constant current source, respectively. The other end of the constant current source is connected to the ground voltage.

With reference to the timing chart of FIG. 1B, the read out (read access) operation is described. The reset signal DISC is enabled, the reset transistors NCHdiscB and NCHdiscRB are turned on, and the bit line BL and the reference bit line RBL are discharged to the ground voltage. The bit line selecting transistor (NCHYj) selected by the bit line selecting signal Yj is turned on, and the selected bit line BL is connected to the sense bit line SBL, and hence the sense bit line SBL is reset to the ground voltage. Further, the respective bit lines (SBL and RBL) of the bit line pair are respectively connected to the first and the second bit lines of the sense amplifier by the bit line connection signal READIN, and hence the first and the second bit lines of the sense amplifier are also reset to the ground voltage.

Next, the equalize signal RSAEQ is enabled, and hence the charge transistors (NCH3 and NCH4) are turned on. In this case, the output of the bit line charge voltage generating circuit 26 is charged to the bit line charge high voltage VBLP that is a high voltage. The bit line charge high voltage VBLP enables the bit line pair (SBL and RBL), the selected bit line BL, and the first and the second bit lines of the sense amplifier to be charged from the ground voltage to the initial voltage. In the following description, the bit line pair (SBL and RBL) that are in the state being connected by the selecting transistor or the bit line connecting transistor, the selected bit line BL, and the first and the second bit lines of the sense amplifier may simply be referred to as the bit line pair, the bit line BL, or the sense bit line SBL, or the reference bit line RBL as a representative.

The bit line charge voltage generating circuit 26 includes an output capacitance, which is charged to the bit line charge high voltage VBLP. The accumulated charges are distributed to the bit lines (SBL and RBL) so as to be the initial voltage. For instance, the bit line charge high voltage VBLP may be 1.2 volts, and the initial voltage may be 0.4 volts. This initial voltage is set to be equal to or lower than the threshold value voltage (Vh) at which the cell data in the memory element Rcell may be rewritten. In this case, the sense bit line SBL of the near end that is close to the bit line charge voltage generating circuit rises in a short period with a little overshoot, while the sense bit line SBL of the far end that is distant from the bit line charge voltage generating circuit rises slowly.

In this way, the selected bit line BL and the bit line pair (SBL and RBL) are charged to the initial voltage. The word line is selected, a selected word line (SWL) becomes the high level, and current flows in the sense bit line in accordance with a resistance of the memory element so that voltage of the sense bit line is lowered. At the same time, on the reference bit line side, the reference constant current source signal REFCON is enabled, and current flows from the constant current source so that voltage of the reference bit line RBL is lowered. The current from the constant current source on the reference bit line side is set to an intermediate current value between the value when the memory element Rcell has the high resistance and the value when the memory element Rcell has the low resistance. According to this setting, as illustrated in FIG. 1B as the bit line pair (SBL and RBL), the voltage of the reference bit line (RBL) becomes the intermediate voltage value between the sense bit line voltage at the high resistance and the sense bit line voltage at the low resistance.

When the voltage difference between the sense bit line and the reference bit line becomes, for example, 100 mV, the bit line connection signal READIN is disabled, and the sense bit line is disconnected from the first bit line 38 of the sense amplifier while the reference bit line is disconnected from the second bit line 39 of the sense amplifier. After that, the latch signal LATCH is enabled so that the sense amplifier SA is supplied with the high power supply voltage SAP and the low power supply voltage SAN. The sense amplifier amplifies the voltage difference between the first bit line and the second bit line. When the amplified signal from the sense amplifier is read out to the outside via the input and output circuit, the read out operation is completed. In addition, at a determination time point when the sense amplifier is enabled, the sense bit line (SBL) and the reference bit line (RBL) are disconnected from the sense amplifier and remains at the intermediate voltage. However, continuously in a determination period in the chart, for convenience of understanding, the amplified voltages of the first bit line and the second bit line from the sense amplifier are illustrated as the sense bit line (SBL) and the reference bit line (RBL).

The case where the above-mentioned basic structure illustrated in FIG. 1A is applied to an actual semiconductor memory device is described with reference to FIGS. 2 to 7. In the following description, a part similar to the above-mentioned basic structure illustrated in FIG. 1A and the operation timing may be denoted by the same reference numeral or symbol so that overlapping description may be omitted.

FIG. 2 illustrates a general structural diagram of a semiconductor memory device 10 according to the embodiment of the present invention. The semiconductor memory device 10 is supplied with a clock, an address, a command, and data from the outside, and the general operation is controlled by these input signals. The semiconductor memory device 10 includes a plurality of banks 0 to 7 and an input circuit. Each bank includes a memory cell array 18 and a row decoder 17, a bit line control circuit 19, a sense amplifier 20, and a column decoder 21 disposed around the memory cell array 18. The operations of the individual banks are the same, and hence only selected one bank is described as follows.

The semiconductor memory device 10 is equipped with input circuits, which include a clock generator 11 supplied with clock signals (CK, /CK, and CKE), a command decoder 12 supplied with commands (/CS, /RAS, /CAS, and /WE), a mode register 13 supplied with addresses (AO to A13 and bank address), a row address buffer 15, and a column address buffer and burst counter 16.

An internal clock generated by the clock generator 11 is delivered to the command decoder 12, a control logic 14, a column decoder 21, a latch circuit 23, and the like. The command decoder 12 is supplied with commands (/CS, /RAS, /CAS, and /WE) and delivers the output to the control logic 14. The mode register 13 is supplied with the address, the bank address signal, and the like, and delivers a mode signal to the control logic 14. The control logic 14 is supplied with the output of the clock generator, the address, and the output of the mode register 13, and delivers various control signals to individual circuits. The row address buffer 15 delivers the input row address to the row decoder 17 and the bit line control circuit 19 in accordance with the control signal. The column address buffer and burst counter 16 delivers the input column address to the column decoder 21 in accordance with the control signal and automatically generates and delivers successive addresses in accordance with a burst length counted by a burst counter.

The row decoder 17 decodes the input address so as to select a word line of the memory cell array. The memory cell array 18 is a memory cell region in which a plurality of memory cells are arranged in matrix. The bit line control circuit 19 selects a bit line based on the selecting signal generated by the column decoder and controls initialization and the like of the bit line. The sense amplifier 20 amplifies information from the memory cell which is selected by the row decoder and connected to the bit line selected by the column decoder 21. The column decoder 21 selects the sense amplifier that amplifies the data from the memory cell and reads out the data via the data control circuit 22, the latch circuit 23, and further an input and output circuit 24 to the outside. The cell data is read out continuously in accordance with the set burst length.

When data is written in the semiconductor memory device, data DQ, which is supplied to the input and output circuit 24 in the opposite direction to the case of reading, is written in the memory cell via the latch circuit 23 and the data control circuit 22. In addition, input and output of the data DQ is performed at high speed in synchronization with the clock. Therefore, a DLL circuit 25 is usually incorporated, and hence the timing adjustment is performed.

With reference to FIG. 3, the detailed structure of the semiconductor memory device according to the embodiment is described. In the memory cell array 18, a plurality of memory cells are arranged in matrix. Many memory cells are arranged corresponding to word lines from the row decoder 17 and corresponding to bit lines which are selected by bit line selecting lines of the bit line control circuit 19. Those are arranged repeatedly with respect to each of the sense amplifiers (20A, 20B, etc.). In FIG. 3, m word lines (SW1, SW2, . . . , SWm) and n bit lines (BL1, BL2, . . . , BLn) are arranged for one sense amplifier. In this case, the word line and the bit line selected by a word decoder and a column address decoder for each sense amplifier have the same address. The word line is selected by the row decoder 17, while the bit line is selected by the bit line control circuit 19.

The bit line control circuit 19 includes bit line selecting lines from the column decoder 21, bit line selecting elements 32, reset elements 37 for resetting the bit line BL, and the like. A selecting signal Yjn (and the inverted signal thereof) from the column decoder 21 is supplied to a gate of the bit line selecting element 32 (transistor) including an NMOS and a PMOS, and to a gate of the reset element 37 (transistor) for setting selected one of the bit lines to the ground voltage. The bit line is selected if the selecting signal thereof is the high level, while it is not selected if the selecting signal thereof is the low level. The sense bit line SBL is connected to the reset transistor 31 for reset. If the reset signal DISC is the high level, the sense bit line SBL is reset to the ground voltage. The sense bit line is connected to the plurality of bit lines via the bit line selecting elements. The selected bit line is reset by the reset transistor that is connected to the sense bit line SBL. On the other hand, the non-selected bit line that is not selected is reset to the ground voltage by the reset transistor 37 (NMOS) of the selecting element portion when the bit selection address signal Yjn becomes the low level while the inverted address becomes the high level.

The sense amplifier 20 A (and 20B) includes not only the sense amplifier but also a bit line connecting transistor 36 for the sense bit line and the reference bit line, and switching elements or charge transistors 34. The sense amplifier includes a flip-flop made of CMOS, and a PMOS and NMOS circuits for supplying the high power supply voltage and the low power supply voltage to the flip-flop. The flip-flop is supplied with the high power supply voltage (SAP) and the low power supply voltage (SAN) by a sense amplifier enable signal RAENB, and hence the data is amplified. The sense amplifier amplifies a voltage difference between the sense bit line from which the data from the memory cell is read out and the reference bit line, and delivers the output thereof to a read out bus RWBUS. The two bit line connecting transistors 36 for connecting the inputs (the first and the second bit lines) of the flip-flop of the sense amplifier with the sense bit line and the reference bit line include NMOS and are turned on or off by the bit line connection signal READIN.

The switching elements 34 of the bit line include charge transistors connected to the bit lines (SBL and RBL) which supply the bit line charge high voltage VBLP to drains of the charge transistors. The charge transistors are respectively turned on by the equalize signal RSAEQ supplied to the gates of the two charge transistors, and hence the bit lines (SBL and RBL) are charged to the same voltage. Further, the reset transistor 33 is provided for resetting the reference bit line RBL. The gate, the drain, and the source of the reset transistor are connected to the reset signal DISC, the reference bit line RBL, and the ground voltage, respectively.

The bit line charge high voltage VBLP is generated by using the bit line charge voltage generating circuit 26. The bit line charge voltage generating circuit 26 charges an overdrive capacitor ODCAP in response to turning on a transistor switched by a capacitor charging signal CAPCON. In response to the equalize signal RSAEQ, the accumulated charges of the capacitor is shared by the bit line pair (SBL and RBL), which are charged to the initial voltage.

The reference bit line RBL is provided with a reference signal generating circuit 27 so as to correspond to the memory cell and the bit line that are connected to the sense bit line SBL. The reference signal generating circuit 27 includes a reference signal capacitor REFCAP, a reference constant current source CIREF, and a switching transistor for connecting the reference constant current source with the reference bit line RBL. The reference signal capacitor REFCAP is connected between the reference bit line and the ground voltage and has a capacitance corresponding to a capacitance of constituent elements connected to the sense bit line including the bit line to be selected. The reference constant current source CIREF is a constant current source for supplying constant current corresponding to the intermediate value between a current which flows in the high resistance of the memory element of the memory cells and a current which flows in the low resistance of the memory element. In this case, the reference bit line is common to the plurality of sense amplifiers. Therefore, if K sense amplifiers are connected, for example, the current source CIREF is required to have a current capacity of K times of the constant current for one sense amplifier.

Between the reference bit line and the reference constant current source, there is provided the switching transistor. When the memory cell data is read out, the switching transistor is turned on so that the reference constant current source lowers the voltage of the reference bit line. In this way, the reference bit line RBL works similarly to the sense bit line SBL that changes in accordance with the data read out from the memory cell, and hence a differential voltage can be supplied to the sense amplifier.

Further, a write circuit section for writing data is connected to the sense bit line. The write circuit section includes a write circuit 28 and a switching transistor for connecting the sense bit line with the write circuit 28. In a write mode, the switching transistor is turned on by a write enable signal WE, and the write data is output on the sense bit line, to thereby write data in the memory cell.

With reference to FIG. 4, a data read out (read access) operation from the memory cell is described. In the following description, numeral inside the parentheses corresponds to the numeral in the diagram. A PRECHARGE command is first supplied to the semiconductor memory device. (1) In the bit line charge voltage generating circuit 26, the capacitor charging signal CAPCON is enabled (LOW), with the result that the overdrive capacitor ODCAP is charged to 1.2 volts, for example. The period for charging the overdrive capacitor ODCAP is not limited particularly but may be any period when the memory cell is not accessed. For instance, the charging can be performed in the period when the bit line selection for selecting the bit line that is connected to the memory cell is not performed.

Next, an ACTIVE command is supplied. (2) The bit line connection signal READIN is enabled (HIGH), with the result that the bit lines of the bit line pair (SBL and RBL) are respectively connected to the inputs of the sense amplifier (first bit line 38 and second bit line 39). Further, (3) one shot reset signal DISC is supplied so that the charges in the node of the bit line pair (SBL and RBL) are discharged, and hence the nodes are reset to the ground voltage. In addition, (4) the capacitor charging signal CAPCON is disabled (HIGH), with the result that the charging of the overdrive capacitor ODCAP is finished.

The row address is input together with the ACTIVE command. (5) The selected bit line selecting line is enabled (HIGH) by the input row address. In this case, the non-selected bit line remains at the low level. (6) The equalize signal RSAEQ of the bit line is enabled (HIGH), with the result that the charges of the overdrive capacitor ODCAP that is charged to 1.2 volts are used for the charge sharing of the node of the bit line pair (SBL and RBL), so as to be the same initial voltage. One end of the overdrive capacitor ODCAP, the selected bit line SLBL, the sense bit line, the reference bit line, one end of the reference signal capacitor REFCAP are all the same initial voltage, e.g., 0.4 volts. In this case, the capacitance value of the overdrive capacitor ODCAP is adjusted in advance so that each node voltage after the charge sharing becomes the initial voltage, e.g., 0.4 volts.

Here, the selected bit line (SLBL) is charged to the initial voltage, and the non-selected bit line is the ground voltage. The node of the memory element Rcell of the memory cell connected to the selected bit line and the access transistor NCHcell (Node C) is charged to the initial voltage. Therefore, if the word line is selected by the word decoder 17, the selected access transistor NCHcell is turned on so that the charges in the Node C can promptly start the discharge. Therefore, high speed read out can be performed. In the conventional example, a charging time is necessary for charging the Node C, but the charging period is not necessary in the present embodiment because the charging is performed in a pre-charge period, and hence high speed read out can be performed. Further, the non-selected bit line remains at the ground voltage, and the Node C of the memory cell connected to the non-selected bit line is the ground voltage and is not charged to the initial voltage. In other words, only the memory cell connected to the selected bit line is charged to the initial voltage, and hence power consumption on the non-selected bit line can be reduced. Therefore, it is possible to obtain the semiconductor memory device that can be read at high speed with low power consumption.

When the bit line pair is charged to, e.g., 0.4 volts, the equalize signal RSAEQ is disabled (LOW) so that the pre-charge is finished. (7) The reference constant current source signal REFCON is enabled so that the reference constant current source is enabled. At the same time, (8) the selected word line is enabled (HIGH) by the row address so that the cell data is read out. Here, for example, it is supposed that the word line (SW2) and the bit line corresponding to the bit line selecting signal Yj2 are selected. In this case, the non-selected bit lines and word lines are the low level. The charge on the sense bit line is discharged via the selected memory cell. (9) If the selected memory cell has high resistance, a voltage drop of the sense bit line is small. In contrast, if the selected memory cell has low resistance, a voltage drop of the bit line is large. Similarly, the discharge is performed via the constant current source CIREF also on the reference bit line RBL for providing the reference threshold value voltage to the sense amplifier. (10) The discharge speed by the constant current source CIREF is adjusted and set so as to be an intermediate value between the discharge speed of the sense bit line in the case where the selected memory cell has high resistance and the discharge speed of the sense bit line in the case where the selected memory cell has low resistance. This constant current source CIREF may be realized by a current mirror circuit using an NMOS transistor, for example. In addition, the constant current source may be realized by a resistor.

In this way, the sense bit line and the reference bit line are discharged by the selected memory cell and the constant current source CIREF so that the their respective voltages are lowered. When the voltage difference between the sense bit line and the reference bit line becomes 100 mV or higher, for example, the bit line connection signal READIN is disabled (LOW) so that the sense amplifier is separated from the bit line pair (SBL and RBL). (11) The disabling of bit line connection signal READIN (LOW) causes the voltage difference between the sense bit line and the reference bit line to be locked.

(12) Next, the sense amplifier enable signal RAENB is enabled (HIGH), and hence the sense amplifier is supplied with the high power supply voltage SAP and the low power supply voltage SAN. (13) In response to the supply of the power supply voltage, the sense amplifier amplifies the voltage difference between the first bit (sense bit) line and the second bit (reference bit) line. Thus, in accordance with whether the selected memory cell has high resistance (reset sate) or low resistance (set state), the sense amplifier produces the ground voltage or the output of the full amplitude voltage between the power supply voltages. At this time point, the bit line pair (SBL and RBL) is separated from the sense amplifier and remain at the intermediate voltage. However, in the determination period in the time chart, for convenience of understanding, voltages amplified by the sense amplifier are illustrated as the sense bit line (SBL) and the reference bit line (RBL). As to the actual operation in this determination period, the sense amplifier performs the full amplitude operation between the ground voltage and the power supply voltage, and the bit line pair (SBL and RBL) has an intermediate voltage operation lower than the voltage between the ground voltage and the power supply voltage.

(14) The amplified data signal is delivered to the read out bus RWBUS by an output logic using a NAND circuit and an inverter, for example. The HIGH level or the LOW level is output on the read out bus RWBUS in accordance with whether or not the selected memory cell has high resistance or low resistance. Next, a READ command and a column address are input. (15) Among cell data items output from the sense amplifiers to the read out bus RWBUS, cell data of the address designated by the input column address and the burst counter is continuously output from the input and output circuit.

Next, the bit line charge voltage generating circuit for generating the bit line charge high voltage VBLP is described. FIG. 5 is a circuit diagram of the bit line charge voltage generating circuit, FIG. 6A is a layout diagram of the bit line charge voltage generating circuit in the bank, and FIG. 6B is a wiring diagram of the bit line charge high voltage VBLP in the mat.

With reference to FIG. 5, the bit line charge voltage generating circuit 26 includes a differential amplifier DEF1, two PMOS's (PCH1 and PCH2), and the overdrive capacitor ODCAP. An inverting terminal of the differential amplifier DEF1 is supplied with a reference voltage VREF1 to be a reference of the bit line charge high voltage VBLP. In addition, a non-inverting terminal of the differential amplifier DEF1 is connected to a voltage supply node VBLPG for the capacitor. Therefore, the voltage of the voltage supply node VBLPG becomes the same voltage as the reference voltage VREF1 via the PMOS PCH1. When the capacitor charging signal CAPCON is enabled (LOW), the overdrive capacitor ODCAP is charged to the voltage VREF1 via the PMOS PCH2. When the overdrive capacitor ODCAP and the bit line pair are short-circuited so that the charge sharing is performed, the capacitor charging signal CAPCON is disabled (HIGH) so that the PMOS PCH2 is turned off. Thus, the charge supply from the voltage supply node VBLPG to the overdrive capacitor ODCAP is ceased. In this case, when the reference voltage VREF1 is 1.2 volts, for example, voltage of the voltage supply node VBLPG also becomes 1.2 volts. The charge stored in the overdrive capacitor ODCAP is adjusted so that the voltage becomes 0.4 volts when the charge sharing is performed with the bit line pair.

The charge sharing from the overdrive capacitor ODCAP to the memory cells arranged in a large area should be performed at high speed and uniformly. In order to perform the charge sharing uniformly with respect to the individual memory cells, it is necessary to reduce resistance of wiring to the memory cell array and to reduce a variation of the resistance depending on the arrangement position. Therefore, the embodiment of the present invention adopts the arrangement as illustrated in FIGS. 6A and 6B.

With reference to FIG. 6A, elements of the overdrive capacitor ODCAP are distributed and arranged along the four sides of the bank in mats, for example, and the bit line charge voltage generating circuits 26 are arranged at four corners of the bank. It is possible to omit the overdrive capacitor ODCAP for the bit line charge voltage generating circuits 26 arranged at four corners and to arrange the overdrive capacitors ODCAP only on the four sides. Further, the wirings of the bit line charge high voltage VBLP are connected to form a mesh for each mat in the bank, and hence a variation of wiring resistance among mats is reduced as much as possible. In other words, in the mat inside the bank, wirings of the bit line charge high voltage VBLP are formed in a cross shape as illustrated in FIG. 6B. The mat is a memory cell array block in a smaller unit constituting the bank. The mat includes a memory cell region in which the word lines and the bit lines are arranged to cross each other in matrix, a word decoder 17, a bit line control circuit 19, and sense amplifiers 20. Several tens of the sense amplifiers 20 may be provided inside one mat, for example.

In this way, the overdrive capacitors ODCAP are distributed and arranged along four sides of the bank, the wirings of the bit line charge high voltage VBLP are formed around the bank and in the cross shape in the mat. According to this structure, the wiring resistance from the overdrive capacitor ODCAP to each mat can be reduced in the bank, and hence every selected bit line can be charged uniformly in a very short time substantially regardless of the mat position.

A write operation of the semiconductor memory device according to the embodiment is described with reference to FIG. 7. The write operation is performed after part of the series of read operations is finished from the ACTIVE command in FIG. 4. Therefore, the series of read operations in the bit line pre-charge period, a bit line floating period and a determination period is performed by the PRECHARG command and the ACTIVE command. In this case, output of the data DQ from the read out bus RWBUS and the input and output circuit is not performed, and hence they are used for receiving write data.

When the determination period is finished, (1) the sense amplifier enable signal RAENB is disabled (LOW). (2) The selected word line and the selected bit line are enabled (HIGH) again by the row address of the ACTIVE command. The non-selected word line and the non-selected bit line remain at the low level. (3) When the WRITE command is input, the column address and the write data are supplied. The data bus RWBUS designated by the input column address is selected, and the write data WDATA is supplied to the write circuit 28. On this occasion, the set is written if the write data WDATA is LOW while the reset is written if the write data WDATA is HIGH.

(4) When the write enable signal WE is supplied to the write circuit, the set current pulse and the reset current pulse corresponding to the write data WDATA are delivered from the write circuit. In this case, the reset current pulse has a larger current value (voltage value) than the set current pulse and is delivered as a short pulse. The output node WPOUT of the write circuit is connected to the selected bit line SLBL via the bit line control circuit 19 during the period when the write enable signal WE is enabled (HIGH). Therefore, the write pulse is supplied to the selected bit line SLBL so that idata of the selected memory cell is rewritten. (5) When information of the selected memory cell is rewritten by the write pulse, a shape of the write pulse is changed steeply by keeping the reset signal DISC to be enabled (HIGH) for a predetermined period so as to discharge the charge in the selected bit line SLBL forcedly. (6) Finally, the write enable signal WE, the selected bit line Yj2, and the selected word line SW2 are disabled (LOW), and the write operation is finished.

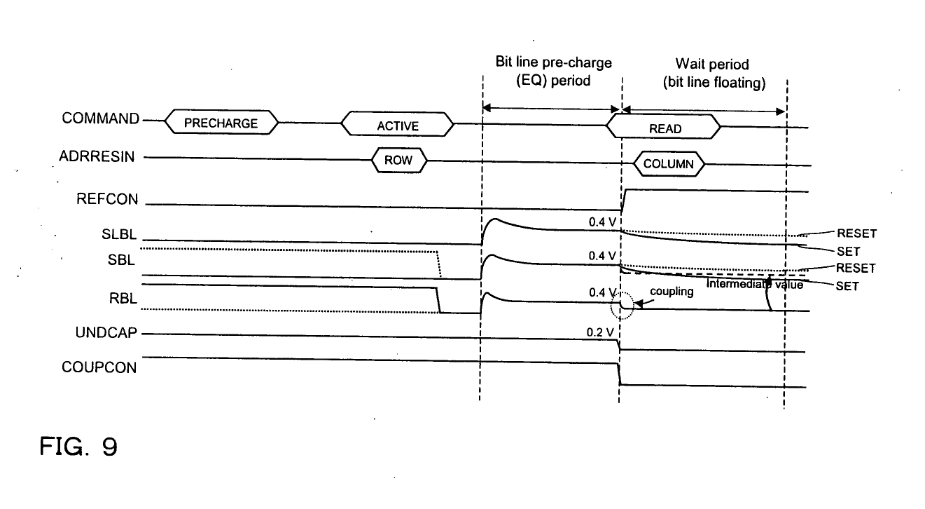

The above-mentioned example shows the case where a current source is used as the reference voltage generating circuit 27 for potential adjustment of the reference bit line. However, as another method, a capacitance coupling may be used for the potential adjustment. The method using a capacitance coupling is described with reference to FIGS. 8 and 9. FIG. 8 is a circuit diagram of the reference voltage generating circuit 27 using a capacitance coupling, and FIG. 9 is a read timing chart thereof.

The reference voltage generating circuit 27 of FIG. 8 includes a power supply (VCOUPL) and two switching transistors that are controlled by a capacitance coupling signal COUPCON and an inverted signal thereof instead of the switching transistor and the reference constant current source CIREF of FIG. 3. The reference signal capacitor REFCAP is connected between the reference bit line RBL and the node UNDCAP, and the reference voltage generating circuit 27 and the reference bit line RBL are coupled to each other by the capacitance coupling via the reference signal capacitor REFCAP.

The gate, the drain, and the source of the switching transistor for setting the node UNDCAP to the ground potential are connected to the inverted signal of the capacitance coupling signal COUPCON, the node UNDCAP, and the ground voltage, respectively. The gate, the drain, and the source of the switching transistor for setting the node UNDCAP to the power supply (VCOUPL) are connected to the capacitance coupling signal COUPCON, the node UNDCAP, and the high voltage side of the power supply (VCOUPL), respectively. The other end (low voltage side) of the power supply (VCOUPL) is connected to the ground voltage. The reference voltage generating circuit 27 using the capacitance coupling has a structure for switching the electrode of the reference signal capacitor REFCAP opposite to the reference bit line to be connected to the ground or to the power supply (VCOUPL).

FIG. 9 illustrates a timing chart of the case using the method by the capacitance coupling. The timing chart illustrated in FIG. 9 is different from the timing chart of FIG. 4 only in timings related to the reference voltage generating circuit 27, and other timings are the same as those of FIG. 4. The timings of signals related to the reference voltage generating circuit 27 are described. Here, the capacitance coupling signal COUPCON is a signal for sensing data of the memory cell and is equivalent to the inverted signal of the reference constant current source signal REFCON of FIG. 4.

The node UNDCAP of the reference voltage generating circuit 27 that is the opposite electrode side of the reference bit line in the reference signal capacitor REFCAP is switched between connections to the power supply (VCOUPL) and to the ground voltage. During the period when the capacitance coupling signal COUPCON is enabled, the switching transistor for setting to the power supply (VCOUPL) is turned on, and the node UNDCAP is connected to the power supply (VCOUPL), and hence a positive voltage of e.g., 0.2 volts is applied. After that, the capacitance coupling signal COUPCON is inverted, a waiting period starts, and the switching transistor for setting the node UNDCAP to the ground potential is turned on. When the charge in the node UNDCAP is discharged to the GND potential, the potential of the reference bit line RBL is decreased by the capacitance coupling via the reference signal capacitor REFCAP.

The amount in decrease of potential is adjusted by the voltage of the power supply VCOUPL and the capacitance of the reference signal capacitor REFCAP, and hence the potential of the reference bit line RBL becomes the intermediate value between the bit line potential in the case where the memory element has the high resistance and the bit line potential in the case where the memory element has the low resistance when the waiting is finished. Thus, the difference voltage between the sense bit line and the reference bit line can be read out by the voltage differential type sense amplifier.

According to the embodiment, the sharing of the charge that is charged to the bit line charge high voltage higher than the initial voltage in the read mode is performed with the sense bit line and the reference bit line, and hence the sense bit line and the reference bit line are set to the initial voltage. Thus, it is possible to provide the semiconductor memory device capable of reducing a read time.

The present invention has been described above with reference to the embodiment, but the present invention is not limited to the above-mentioned embodiment. Various modifications may me made to the structure and the detail of the embodiment within the scope of the present invention.

The present invention may be applied to various semiconductor devices including the non-volatile memory element. The present invention is useful particularly for a phase change memory (PCRAM), a resistance change memory (ReRAM), a non-volatile memory having resistance change non-volatile memory elements on cross points of the word lines and the bit lines, and the like.

The present invention may be applied to various resistance change non-volatile semiconductor devices. Specifically, the present invention may be applied to general semiconductor products such as a central processing unit (CPU) having a resistance change non-volatile information storage function, a micro control unit (MCU), a digital signal processor (DSP), an application specific integrated circuit (ASIC), and an application specific standard circuit (ASSP). In addition, the device to which the present invention is applied may be used for a semiconductor device such as a system-on-chip (SOC), a multichip package (MCP), or a package on package (POP). In addition, it is sufficient if the transistor that is used for the memory cell and the logic circuit is a field effect transistor (FET), and the transistor may be various FETs such as a metal-insulator semiconductor (MIS) or a thin film transistor (TFT) as well as the metal oxide semiconductor (MOS). Some transistors may be transistors other than the FET. In addition, a P-channel transistor or a PMOS transistor constituting the so-called CMOS logic circuit is a typical example of a first conductive type transistor, while an N-channel transistor or an NMOS transistor is a typical example of a second conductive type transistor. Further, the substrate is not limited to a P type semiconductor substrate, but may be an N type semiconductor substrate or a semiconductor substrate having a silicon on insulator (SOI) structure, or some other semiconductor substrate.

What is claimed is:

1. A device comprising:
at least one memory array including a plurality of memory cells, each of the memory cells adapted to store data based on a difference of resistance;
a plurality of bit lines each arranged to be connected to the memory cells;
a sense amplifier of a voltage differential type;
a voltage generating circuit adapted to charge a selected bit line and a reference bit line to a first voltage higher than an initial voltage prior to access;
a first switch and a second switch controlled to couple the voltage generating circuit to the selected bit line and the reference bit line, respectively; and
a reference voltage generating circuit capable of being coupled to the reference bit line;
wherein, in the access, the first switch and the second switch are tuned on in a pre-charge period before the memory cell is accessed so that charges provided by the voltage generating circuit are distributed to share between the selected bit line and the reference bit line, to thereby charge the selected bit line and the reference bit line to the initial voltage; and
wherein, after pre-charge, a selected memory cell is connected to the selected bit line, the reference bit line is connected to the reference voltage generating circuit, and the sense amplifier amplifies a difference voltage between a voltage of the selected bit line decreased by discharge of the selected memory cell and a voltage of the reference bit line developed by coupling to the reference voltage generating circuit.

2. A device according to claim 1,
wherein the memory cells include a memory element and a cell selecting element;
the memory element is arranged between the bit line and a terminal of the cell selecting element; and
a node of the memory element and the terminal of the cell selecting element is charged to the initial voltage in the pre-charge period.

3. A device according to claim 1, further comprising:
a third switch adapted to select at least one of the bit lines and connect the selected bit line to a sense bit line, the third switch being enabled by bit line address selection, and the selected bit line is charged to the initial voltage in the pre-charge period.

4. A device according to claim 3, further comprising:
a fourth switch and a fifth switch controlled to couple or decouple the sense bit line with a first input line of the sense amplifier and the reference bit line with a second input line of the sense amplifier, respectively;
wherein the sense amplifier is decoupled from the sense bit line and the reference bit line by disabling the fourth switch and the fifth switch in a determination period of data.

5. A device according to claim 4,
wherein a connection point of the first switch with the sense bit line is arranged between a connection point of the third switch with the sense bit line and a connection point of the fourth switch with the sense bit line.

6. A device according to claim 1, further comprising:
reset elements adapted to reset the selected bit line and the reference bit line to a ground voltage prior to the pre-charge period.

7. A device according to claim 1,
wherein the voltage generating circuit includes an overdrive capacitor which is charged to the first voltage in a period from input of a pre-charge command until a bit line selection operation of the memory cell.

8. A device comprising:
a bank including a block of multiple mats arranged in matrix;
each mat including a memory array which includes a of a plurality of memory cells adapted to store data based on a difference of resistance, a plurality of bit lines each arranged to be connected to the memory cells, and at least one sense amplifier of a voltage differential type;
voltage generating circuits disposed at corners of the block, each of voltage generating circuits adapted to charge a selected bit line and a reference bit line to a first voltage higher than an initial voltage prior to access,
a first switch and a second switch controlled to couple the voltage generating circuit to the sense bit line and the reference bit line, respectively;
override capacitors arranged along four sides of the block and coupled to the voltage generating circuits;
power supply voltage wirings formed across the block so as to form a cross shape in each mat, the power supply voltage wirings connected to the override capacitors and the voltage generating circuit; and
a reference voltage generating circuit capable of being coupled to the reference bit line;
wherein, in the access, the first switch and the second switch are tuned on in a pre-charge period before the memory cell is accessed so that charges provided by the voltage generating circuit are distributed to share between the selected bit line and the reference bit line, to thereby charge the selected bit line and the reference bit line to the initial voltage; and
wherein, after pre-charge, a selected memory cell is connected to the selected bit line, the reference bit line is connected to the reference voltage generating circuit, and the sense amplifier amplifies a difference voltage between a voltage of the selected bit line decreased by discharge of the selected memory cell and a voltage of the reference bit line developed by coupling to the reference voltage generating circuit.

9. A device according to claim 8,
wherein the memory cells include a memory element and a cell selecting element;
the memory element is arranged between the bit line and a terminal of the cell selecting element; and
a node of the memory element and the terminal of the cell selecting element is charged to the initial voltage in the pre-charge period.

10. A device according to claim 8, further comprising:
a third switch adapted to select at least one of the bit lines and connect the selected bit line to a sense bit line, the third switch being enabled by bit line address selection, and the selected bit line is charged to the initial voltage in the pre-charge period.

11. A device according to claim 10, further comprising:
a fourth switch and a fifth switch controlled to couple or decouple the sense bit line with a first input line of the sense amplifier and the reference bit line with a second input line of the sense amplifier, respectively;
wherein the sense amplifier is decoupled from the sense bit line and the reference bit line by disabling the fourth switch and the fifth switch in a determination period of data.

12. A device according to claim 11,
wherein a connection point of the first switch with the sense bit line is arranged between a connection point of the third switch with the sense bit line and a connection point of the fourth switch with the sense bit line.

13. A device according to claim 8, further comprising:
reset elements adapted and to reset the selected bit line and the reference bit line to a ground voltage prior to the pre-charge period.

14. A device according to claim 8,
wherein the voltage generating circuit includes an overdrive capacitor which is charged to the first voltage in a period from input of a pre-charge command until a bit line selection operation of the memory cell.

15. A method comprising:
reading data from a device,
wherein the device comprises a plurality of memory cells adapted to store data by a difference of resistance; a plurality of bit lines each connected to the memory cells; a sense amplifier adapted to amplify a voltage difference between a selected bit line and a reference bit line developed by selecting a memory cell; and a charge voltage generating circuit:
the reading data from the device comprising:
charging an output capacitance of the charge voltage generating circuit to a high voltage higher than an initial voltage;
supplying charges that are charged to the high voltage to the selected bit line and the reference bit line, so as to set the selected bit line and the reference bit line to the initial voltage;
discharging the selected bit line in accordance with data stored in a selected memory cell; and
amplifying a difference voltage between a voltage of the discharged selected bit line and the voltage of the reference bit line by the sense amplifier, to thereby read out the stored data of the memory cell.

16. A method according to claim 15, wherein the charging the output capacitance to the high voltage is performed during a period in which a selection of a bit line among a plurality of the bit lines is not performed.

17. A method according to claim 15, further comprising, in the reading data from the device, resetting the bit line and the reference bit line to a ground voltage after the charging the output capacitance to the high voltage and before the setting the bit line and the reference bit line to the initial voltage.

18. A method according to claim 15, wherein the setting the bit line and the reference bit line to the initial voltage is performed after a bit line is selected among a plurality of the bit lines.

19. A method according to claim 15, wherein the discharging the bit line comprises discharging the reference bit line by a constant current source.

20. A method according to claim 15, wherein the discharging the bit line comprises decreasing the voltage of the reference bit line by a capacitance coupling.
